(19) United States
(12) Patent Application Publication
(10) Pub. No.: US 2023/0182752 A1
(43) Pub. Date: Jun. 15, 2023

(54) INTERFACE CIRCUIT, ELECTRONIC CONTROL UNIT SYSTEM, AND METHODS OF OPERATING DEVICES USING AN ELECTRONIC CONTROL UNIT

(71) Applicant: Continental Automotive Technologies GmbH, Hannover (DE)

(72) Inventor: Marcos Narvaez Soriano, Singapore (SG)

(73) Assignee: Continental Automotive Technologies GmbH, Hannover (DE)

(21) Appl. No.: 18/078,017

(22) Filed: Dec. 8, 2022

(30) Foreign Application Priority Data
Dec. 13, 2021 (GB) 2117975.9

(51) Int. Cl. B60W 50/02; B60R 16/03; B60R 16/023

(52) U.S. Cl. CPC B60W 50/0205; B60R 16/03; B60R 16/0231

(57) ABSTRACT

According to various embodiments, there is provided an interface circuit for connecting to an electronic control unit (ECU). The interface circuit may include a first connection circuit, a second connection circuit, and a switching circuit. The first connection circuit may be configured to connect to an external device. The second connection circuit may be configured to provide an input signal to an ECU. The input signal may be indicative of a voltage level at the first connection circuit. The switching circuit may be connectable to a first voltage and a second voltage. The switching circuit may be configured to receive a control signal from the ECU, and may be further configured to selectively connect the first connection circuit to one of the first voltage and the second voltage, based on the received control signal.

### TECHNICAL FIELD

Various embodiments relate to interface circuits for connecting to an electronic control unit (ECU) and ECU systems. Various embodiments also relate to methods of operating devices such as sensor device or load device, using an ECU.

### BACKGROUND

Modern automotive vehicles include multiple automotive ECUs to perform various functions. These ECUs may include, for example, body controller module, zone controller module and others. The ECU may be used as an input interface, to detect or measure electrical automotive sensors such as thermostats and switches, for example ignition and control switches. The ECU may also be used as an output driver, to drive or actuate electro-mechanical load devices, for example, relays, solenoids, direct-current motors, lamps, and light emitting diodes (LED). The ECUs typically include dedicated input interface circuits and output driver circuits for connecting to each electro-mechanical load device, or electrical automotive sensor. For example, the ECU may include an input interface circuit that is either active-low or active-high, depending on the type of sensor that would be connected to the input interface circuit. For example, the ECU may include an output driver circuit that is either high-side or low-side driver circuit, depending on the type of load device that would be connected to the output driver circuit. Each of these individual active-low input interface circuit, active-high input interface circuit, high-side output driver circuit and low-side output driver circuit would require dedicated wiring for connecting to the sensors or to the load devices. Consequently, the ECU would require big cable harnesses and multiple mating connectors in order to connect to the various types of devices. These big cable harnesses and mating connectors add undesirable weight and cost to the vehicle. Further, during the development process of a new vehicle, if there is a need to rewire the ECU connection from a sensor to a load device, or vice versa, the ECU would need to undergo a major hardware change. The hardware change will involve efforts such as change in the circuit board layout, and revalidation efforts, which translates into time and cost impact to both the vehicle manufacturer and the ECU supplier.

### SUMMARY

According to various embodiments, there may be provided an interface circuit for connecting to an electronic control unit (ECU). The interface circuit may include a first connection circuit, a second connection circuit, and a switching circuit. The first connection circuit may be configured to connect to an external device. The second connection circuit may be configured to provide an input signal to an electronic control unit. The input signal may be indicative of a voltage level at the first connection circuit. The switching circuit may be connectable to a first voltage and a second voltage. The switching circuit may be configured to receive a control signal from the electronic control unit, and may be further configured to selectively connect the first connection circuit to one of the first voltage and the second voltage, based on the received control signal.

According to various embodiments, there may be provided an ECU system. The ECU system may include the abovementioned interface circuit and an ECU connected to the interface circuit.

According to various embodiments, there may be provided a method of operating a sensor device using an ECU. The method may include connecting the ECU to the abovementioned interface circuit and connecting the sensor device to the first connection circuit of the interface circuit. The first connection circuit may be connected to the switching circuit via a wetting current resistor.

According to various embodiments, there may be provided a method of operating a load device using an ECU. The method may include connecting the ECU to the abovementioned interface circuit and connecting the load device to the first connection circuit of the interface circuit. The first connection circuit may be connected to the switching circuit via a jumper cable.

According to various embodiments, there may be provided a method of diagnosing for fault conditions in an external device using an ECU. The method may include connecting the ECU to the abovementioned interface circuit, connecting the external device to the first connection circuit of the interface circuit, connecting the diagnostic sub-circuit of the interface circuit to a reference voltage, and setting the control signal to logic low to disconnect the external device from the power supply.

Additional features for advantageous embodiments are provided in the dependent claims.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 shows a conceptual diagram of an interface circuit according to various embodiments.

FIG. 2 shows a schematic diagram of an interface circuit according to various embodiments.

FIG. 3 shows a circuit diagram of an interface circuit according to various embodiments.

FIG. 4 shows an ECU system according to various embodiments.

FIG. 5 shows a flow diagram of a method of operating a sensor device using an ECU, according to various embodiments.

FIG. 6A shows an annotated circuit diagram of an interface circuit, when the interface circuit is in use to carry out the method of FIG. 5, according to various embodiments.

FIG. 6B shows an annotated circuit diagram of an interface circuit, when the interface circuit is in use to carry out the method of FIG. 5, according to various embodiments.

FIG. 6C shows an annotated circuit diagram of an interface circuit, when the interface circuit is in use to carry out the method of FIG. 5, according to various embodiments.

FIG. 7 shows a flow diagram of a method of operating a load device using an ECU, according to various embodiments.

FIG. 8A shows an annotated circuit diagram of an interface circuit when the interface circuit is in use to carry out the method of FIG. 7, according to various embodiments.

FIG. 8B shows an annotated circuit diagram of an interface circuit when the interface circuit is in use to carry out the method of FIG. 7, according to various embodiments.

FIG. 9 shows a flow diagram of a method of diagnosing for fault conditions in an external device using an ECU, according to various embodiments.

### DETAILED DESCRIPTION

Embodiments described below in context of the devices, such as interface circuits or electronic control unit systems, are analogously valid for the respective methods, and vice versa. Furthermore, it will be understood that the embodiments described below may be combined, for example, a part of one embodiment may be combined with a part of another embodiment.

It will be understood that any property described herein for a specific device, such as interface circuit or electronic control unit system, may also hold for any device described herein. It will be understood that any property described herein for a specific method may also hold for any method described herein. Furthermore, it will be understood that for any device or method described herein, not necessarily all the components or steps described must be enclosed in the device or method, but only some (but not all) components or steps may be enclosed.

The term “coupled” (or “connected”) herein may be understood as electrically coupled or as mechanically coupled, for example attached or fixed, or just in contact without any fixation, and it will be understood that both direct coupling or indirect coupling (in other words: coupling without direct contact) may be provided.

In an embodiment, a “circuit” may be understood as an electrical circuit or any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g., a microprocessor (e.g., a Complex Instruction Set Computer (CISC) processor or a Reduced Instruction Set Computer (RISC) processor). An electrical circuit, or merely “circuit” may be understood to be any kind of electricity-conducting path, including for example, an electrical wire, an input connector, or an output connector. An electrical circuit may also include one or more electrical components that are electrically connected by an electrical wire. A “circuit” may also be a processor executing software, e.g., any kind of computer program, e.g., a computer program using a virtual machine code such as e.g., Java. Any other kind of implementation of the respective functions which will be described in more detail below may also be understood as a “circuit” in accordance with an alternative embodiment.

The terms “high” and “low” used herein with respect to voltages, may be understand as relative terms, in other words, a “high” voltage may be of a higher value than a “low” voltage. For example, a high voltage may be 5V while a low voltage may be 0V, or a high voltage may be 10V while a low voltage may be 5V, or a high voltage may be 0V while a low voltage may be ˜5V.

The connecting interfaces of conventional automotive ECUs are typically specifically adapted to the external device that is to be connected to the ECU. For example, the connecting interface to a sensor device may be different from the connecting interface to an electro-mechanical load device. Also, the connecting interface to an active-high sensor device may be different from the connecting interface to an active-low sensor device. Similarly, the connecting interface to a high-side load device may be different from the connecting interface to a low-side load device. Yet another connecting interface may be required for the ECU to perform a diagnostic test on the external device. As a result, the vehicle may need to be equipped with a plurality of different mating connector types and cable harnesses, for connecting various external devices to respective ECUs. Moreover, if the type of external device connected to an ECU is changed, the affected ECU hardware may need to be modified in order to provide the appropriate connecting interface to match the new external device.

According to various embodiments, an interface circuit that is connectable to an ECU may address the abovementioned problems, by being selectively configurable between the functions of active-high input sensing, active-low input sensing, high-side output driver, low-side output driver, and diagnostic sensing, without the need for any major hardware change. By virtue of being configurable between the various functions without any substantial hardware changes, the interface circuit may mitigate the need to perform hardware modifications to the ECU when the ECU needs to be connected to a different external device. Also, the quantity of wires and ECU mating connectors required in a vehicle may be reduced, as the interface circuit may allow the ECU to be connected to any one of active-high input sensor, active-low input sensor, high-side load device, and low-side load device. The interface circuit may be provided as part of a new ECU, that includes the interface circuit in place of a conventional connecting interface. Alternatively, the interface circuit may be provided as an external component that may be coupled to a conventional ECU.

In order that the invention may be readily understood and put into practical effect, various embodiments will now be described by way of examples and not limitations, and with reference to the figures.

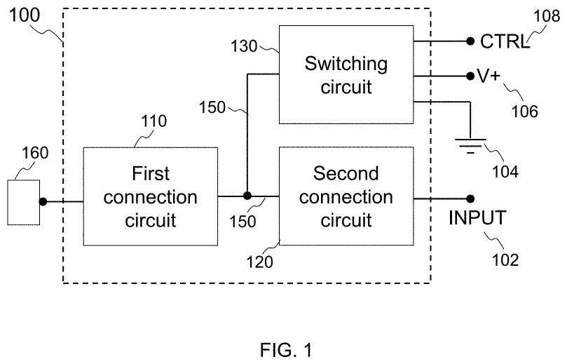

FIG. 1 shows a conceptual diagram of an interface circuit 100 according to various embodiments. The interface circuit 100 may be connectable to an ECU. The interface circuit 100 may include a first connection circuit 110, a second connection circuit 120, and a switching circuit 130. The first connection circuit 110 may be configured to connect to an external device 160. The second connection circuit 120 may be configured to provide an input signal 102 to an ECU. The input signal 102 may be indicative of a voltage level at the first connection circuit 110. The switching circuit 130 may be connectable to a first voltage 104 and a second voltage 106. The switching circuit 130 may be configured to receive a control signal 108 from the ECU. The switching circuit 130 may be further configured to selectively connect the first connection circuit 110 to one of the first voltage 104 and the second voltage 106, based on the received control signal 108. The first connection circuit 110, the second connection circuit 120, and the switching circuit 130 may be coupled with each other, like indicated by lines 150, for example electrically coupled, for example using a line or a cable, and/or communicatively coupled.

In other words, the interface circuit 100 may be connectable to an ECU, to receive a control signal 108 from the ECU. The interface circuit 100 may also provide an input signal 102 to the ECU. The input signal 102 may be provided to an input port of a microcontroller or central processing unit of the ECU. The interface circuit 100 may include a first connection circuit 110 and may connect to an external device 160 via the first connection circuit 110. The interface circuit 100 may also include a switching circuit 130 that may be connected to a first voltage 104 and a second voltage 106. The interface circuit 100 may receive the control signal through the switching circuit 130. Depending on the control signal 108 received, the switching circuit 130 may connect the first connection circuit 110, and thereby the external device 160 by virtue of being connected to the first connection circuit, to either the first voltage 104 or the second voltage 106. The interface circuit 100 may further include a second connection circuit 120. The second connection circuit 120 may be coupled to the first connection circuit 110. The second connection circuit 120 may receive a voltage signal from the first connection circuit 110 and may provide the input signal 102 based on the received voltage signal. The voltage signal may be a voltage level at the output of the first connection circuit 110. The input signal 102 may be indicative of the voltage signal.

The first voltage 104 may be of a lower voltage level than the second voltage 106. The first voltage 104 may be an electrical ground, in other words, at least substantially zero volts, for example, within a range of about −0.1V to −1.0V. The second voltage 106 may be provided by a power supply source. In an alternative embodiment, the first voltage 104 may be a negative voltage level while the second voltage 106 may be a positive voltage level.

The interface circuit 100, when paired with an ECU, may be selectively configurable between the functions of active-high input sensing, active-low input sensing, high-side output driver, and low-side output driver, by using the ECU to adjust the control signal 108 provided to the interface circuit 100.

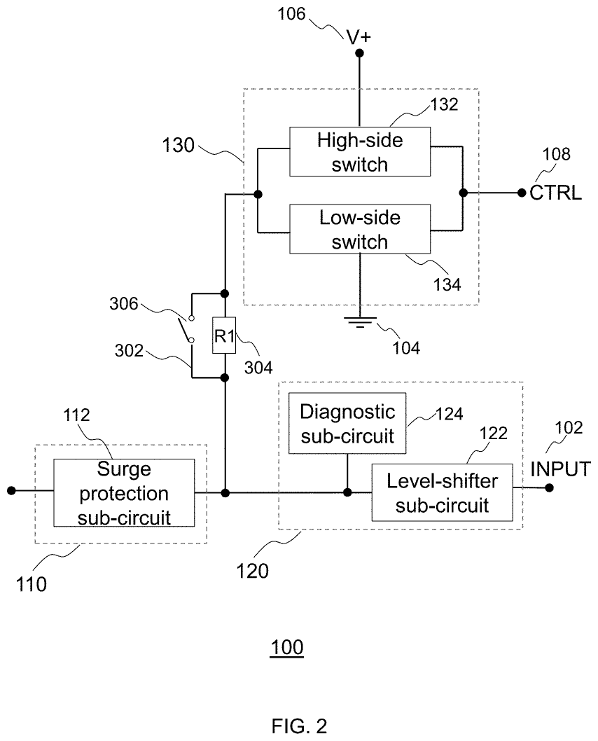

According to an embodiment which may be combined with the above-described embodiment or with any below described further embodiment, the switching circuit 130 may include a high-side switch connectable to the second voltage 106 and a low-side switch connectable to the first voltage 104, for example, as shown in FIG. 2. The switching circuit 130 may be configured to selectively switch on only one of the high-side switch and the low-side switch, based on the received control signal 108.

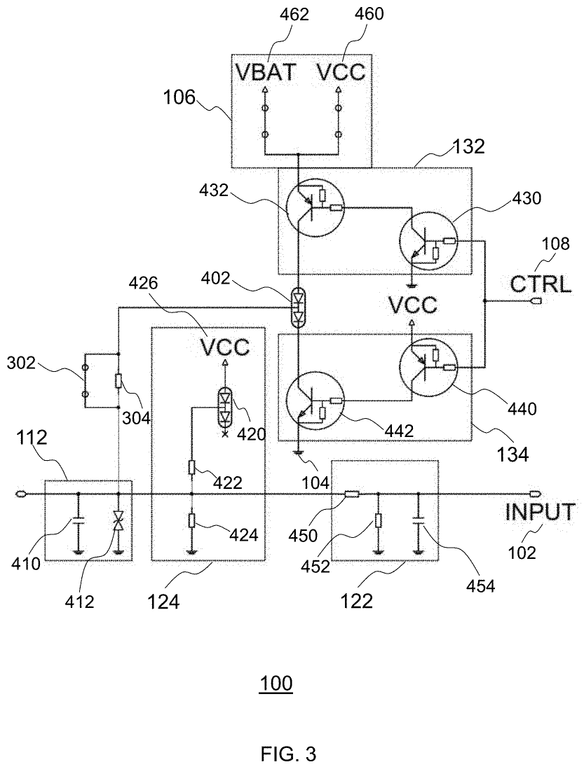

According to an embodiment which may be combined with the above-described embodiment or with any below described further embodiment, the high-side switch may include a first high-side transistor configured to receive the control signal 108 and may further include a second high-side transistor connectable to the second voltage 106, wherein the first high-side transistor may be configured to switch on the second high-side transistor based on the received control signal 108, for example, as shown in FIG. 3. The first high-side transistor, when it is turned on, may allow current to flow through itself such that the second high-side transistor is also turned on.

According to an embodiment which may be combined with any above-described embodiment or with any below described further embodiment, each of the first high-side transistor and the second high-side transistor may be a bipolar junction transistor (BJT), for example, as shown in FIG. 3. A base terminal of the first high-side transistor may be configured to receive the control signal 108, while a collector terminal of the first high-side transistor may be connected to a base terminal of the second high-side transistor. An emitter terminal of the second high-side transistor may be connectable to the second voltage 106.

According to an embodiment which may be combined with any above-described embodiment or with any below described further embodiment, the low-side switch may include a first low-side transistor configured to receive the control signal 108 and may further include a second low-side transistor connectable to the first voltage 104, for example, as shown in FIG. 3. The first low-side transistor may be configured to switch on the second low-side transistor based on the received control signal 108.

According to an embodiment which may be combined with any above-described embodiment or with any below described further embodiment, each of the first low-side transistor and the second low-side transistor may be a BJT, for example, as shown in FIG. 3. The base terminal of the first low-side transistor may be configured to receive the control signal 108. The collector terminal of the first low-side transistor may be connected to the base terminal of the second low-side transistor. The emitter terminal of the second low-side transistor may be connectable to the first voltage 104.

According to an embodiment which may be combined with any above-described embodiment or with any below described further embodiment, the first connection circuit 110 may be connected to the switching circuit 130 via one of a wetting current resistor and a jumper cable. The jumper cable may have a very low resistance, for example, 0Ω. Connecting the first connection circuit 110 to the switching circuit 130 via the jumper cable may allow electrical current to flow between the first connection circuit 100 and the switching circuit 130 with minimal loss of electrical power, and thus provides a higher power to a load device that is being driven by the ECU. On the other hand, connecting the first connection 110 to the switching circuit 130 via the wetting current resistor, when the first connection circuit 100 is connected to a sensor device, may provide a small amount of wetting current to the sensor device. The wetting current may break through surface film resistance at electrical contacts connecting to, or part of the sensor device, so that electrical current may flow between the sensor device and the first connection circuit 110.

According to an embodiment which may be combined with any above-described embodiment or with any below described further embodiment, the first connection circuit 110 may be configured to at least partially absorb voltage surges. In absorbing the voltage surges, the first connection circuit 110 may prevent voltage surges or electrostatic discharges, from damaging the components of the ECU, for example the microcontroller.

According to an embodiment which may be combined with any above-described embodiment or with any below described further embodiment, the second connection circuit 120 may include a level-shifter sub-circuit configured to translate the voltage level at the first connection circuit 110 to a safe voltage level for the ECU, as the input signal 102. By translating the voltage level to a safe voltage level for the ECU, the second connection circuit 120 may prevent voltages that are too large from reaching the ECU, and as such, prevents damaging components of the ECU, for example the microcontroller. The second connection circuit 120 may also translate the voltage level at the first connection circuit 110 to the logic voltage level state that is recognizable by a microcontroller of the ECU.

According to an embodiment which may be combined with any above-described embodiment or with any below described further embodiment, the second connection circuit 120 may include a diagnostic sub-circuit. The diagnostic sub-circuit may be configured to detect a fault at the external device 160 and may be further configured to provide an error signal as the input signal 102 based on detection of the fault. The diagnostic sub-circuit may thus enable the interface circuit 100 to also perform a diagnostic function, on top of being an input interface and for driving load devices.

According to an embodiment which may be combined with any above-described embodiment or with any below described further embodiment, the second connection circuit 120 may be connected to the first connection circuit 110 in series.

According to an embodiment which may be combined with any above-described embodiment or with any below described further embodiment, one or more of the BJTs in the integrated circuit 100 may be replaced by other types of transistors, such as field effect transistor (FET), for example, metal-oxide-semiconductor field-effect transistor (MOSFET). MOSFET transistors may be capable of handling higher power as compared to BJTs.

FIG. 2 shows a schematic diagram of an interface circuit 100 according to various embodiments. The switching circuit 130 may include a high-side switch 132 and a low-side switch 134. The high-side switch 132 and the low-side switch 134 may be connected in parallel. Each of the high-side switch 132 and the low-side switch 134 may be configured to receive the control signal 108. The high-side switch 132 may be configured to receive the second voltage 106, while the low-side switch 134 may be configured to connect to the first voltage 104. The first voltage 104 may be lower than the second voltage 106. The first voltage 104 may be an electrical ground as depicted in FIG. 2. In an alternative embodiment, the first voltage 104 may be a negative voltage while the second voltage 106 may be a positive voltage.

The high-side switch 132 and the low-side switch 134 may be configured such that they turn on based on different voltage levels of the control signal 108. The high-side switch 132 and the low-side switch 134 may turn on mutually exclusively, based on the control signal 108. For example, the high-side switch 132 may turn on when the control signal 108 is logic HIGH (also referred herein simply as “HIGH”), and may turn off when the control signal 108 is logic LOW (also referred herein simply as “LOW”). In the same example, the low-side switch 134 may turn on when the control signal 108 is LOW, and may turn off when the control signal 108 is logic HIGH. The logic HIGH control signal 108 may have a voltage level that is more than 0V, for example, 1 to 10V, for example 5V. The logic LOW control signal 108 may have a voltage level that is lower than logic HIGH, for example, 0V.

Referring to FIG. 2, according to various embodiments, the interface circuit 100 may further include a wetting current resistor 304 (denoted as “R1” in FIG. 2). The wetting current resistor 304 may be arranged between the first connection circuit 110 and the switching circuit 130. The wetting current resistor 304 may be connected to the first connection circuit 110 and the switching circuit 130 in series.

Still referring to FIG. 2, according to various embodiments, the interface circuit 100 may further include a jumper cable 302. The jumper cable 302 may be arranged between the first connection circuit 110 and the switching circuit 130. The jumper cable 302 may be connected to the first connection circuit 110 and the switching circuit 130 in series. The jumper cable 302 may be a purpose-built cable, or may be any electrically conductive cable.

According to various embodiments, the interface circuit 100 may include both the wetting current resistor 304 and the jumper cable 302. The wetting current resistor 304 and the jumper cable 302 may be connected in parallel. The interface circuit 110 may optionally further include a jumper switch 306, for selectively connecting or disconnecting the jumper cable 302. When the jumper cable 302 is connected, electrical current between the first connection circuit 110 and the switching circuit 130 may flow through the jumper cable 302. When the jumper cable 302 is disconnected, electrical current between the first connection circuit 110 and the switching circuit 130 may flow through the wetting current resistor 304 instead.

Still referring to FIG. 2, according to various embodiments, the first connection circuit 110 may be configured to at least partially absorb voltage surges. The first connection circuit 110 may include a surge protection sub-circuit 112 that at least partially absorbs electrostatic discharge or spikes in the voltage level. The first connection circuit 110 may include a connector (not shown in FIG. 2) for electrically coupling with an external device, such as a sensor device or a load device.

Still referring to FIG. 2, according to various embodiments, the second connection circuit 120 may be connected to the first connection circuit 110 in series. The second connection circuit 120 may include a level-shifter sub-circuit 122. The level-shifter sub-circuit 122 may be configured to receive a first voltage (also referred herein as the voltage level at the first connection circuit 110) from the first connection circuit 110. The level-shifter sub-circuit 122 may be further configured to convert the first voltage to a second voltage, and may transmit the second voltage as the input signal 102, to the ECU. The second voltage may be within the safety thresholds of the ECU. The second voltage may be lower than the first voltage, when the first voltage exceeds a safe voltage level for the ECU.

The second connection circuit 120 may further include a diagnostic sub-circuit 124. The diagnostic sub-circuit 124 may be arranged between the first connection circuit 110 and the level-shifter sub-circuit 122. The diagnostic sub-circuit 124 may be configured to detect a disconnected load fault, for example, when it detects an open circuit at the first connection circuit 110. The diagnostic sub-circuit 124 may be configured to provide an error signal to the level-shifter sub-circuit 122 based on detection of the disconnected load fault. The level-shifter sub-circuit 122 may receive the error signal from the diagnostic sub-circuit 124, and may convert the error signal to the second voltage which may be transmitted to the ECU, as the input signal 102.

FIG. 3 shows a circuit diagram of the interface circuit 100 according to various embodiments. The high-side switch 132 may include a first high-side transistor 430 and a second high-side transistor 432. The first high-side transistor 430 may be configured to receive the control signal 108 and may be further configured to transmit a high-side switching signal to the second high-side transistor 432. The second high-side transistor 432 may be connectable to the second voltage 106. The second voltage 106 may be provided by a power supply source including battery power 462, denoted in FIG. 3 as “V_{BAT}”, and common-collector power 460, denoted in FIG. 3 as V_{cc}. The second high-side transistor 432 may be turned on based on the high-side switching signal. Each of the first high-side transistor 430 and the second high-side transistor 432 may be BJTs. The first high-side transistor 430 may be a negative-positive-negative (NPN) transistor, while the second high-side transistor 432 may be a positive-negative-positive (PNP) transistor. The emitter terminal of the first high-side transistor 430 may be connected to electrical ground. When in use, the base terminal of the first high-side transistor 430 may receive the control signal 108. The collector terminal of the first high-side transistor 430 may be connected to the base terminal of the second high-side transistor 432. When in use, the emitter terminal of the second high-side transistor 432 may be connected to the second voltage 106. If the control signal 108 is HIGH, the voltage at the base terminal of the first high-side transistor 430 may be higher than the voltage at the emitter terminal of the first high-side transistor 430, and as such, the first high-side transistor 430 is turned on, and an electrical current flow between its collector and emitter terminals. Consequently, the voltage at the base terminal of the second high-side transistor 432 may be lower than the voltage at the emitter terminal of the second high-side transistor 432, and thus, an electrical current flows between its collector and emitter terminals.

Conversely, if the control signal 108 is LOW, the voltage at the base terminal of the first high-side transistor 430 may be equal to, or lower, than the voltage at the emitter terminal of the first high-side transistor 430, and as such, the first high-side transistor 430 is turned off, and electrical current may not flow between its collector and emitter terminals. Consequently, the voltage at the base terminal of the second high-side transistor 432 may be infinite, due to the open circuit resulting from the first high-side transistor 430 being turned off. As a result, the second high-side transistor 432 may also be turned off, and electrical current may not flow between its collector and emitter terminals.

Still referring to FIG. 3, according to various embodiments, the low-side switch 134 may include a first low-side transistor 440 and a second low-side transistor 442. The first low-side transistor 440 may be configured to receive the control signal 108 and may be further configured to transmit a low-side switching signal to the second low-side transistor 442. The second low-side transistor 442 may be connectable to the first voltage 104. The second low-side transistor 442 may be turned on based on the low-side switching signal. Each of the first low-side transistor 440 and the second low-side transistor 442 may be BJTs. The first low-side transistor 440 may be a PNP transistor, while the second low-side transistor 442 may be an NPN transistor. The emitter terminal of the first low-side transistor 440 may be connected to a common collector voltage (V_{cc}). When in use, the base terminal of the first low-side transistor 440 may receive the control signal 108. The collector terminal of the first low-side transistor 440 may be connected to the base terminal of the second low-side transistor 442. When in use, the emitter terminal of the second low-side transistor 442 may be connected to the first voltage 104. If the control signal 108 is LOW, the voltage at the base terminal of the first low-side transistor 440 may be lower than the voltage at the emitter terminal of the first low-side transistor 440, and as such, the first low-side transistor 440 is turned on, and an electrical current flow between its collector and emitter terminals. Consequently, the voltage at the base terminal of the second low-side transistor 442 may be higher than the voltage at the emitter terminal of the second low-side transistor 442, and thus, an electrical current flows between its collector and emitter terminals.

Conversely, if the control signal 108 is HIGH, the voltage at the base terminal of the first low-side transistor 440 may be equal to, or higher, than the voltage at the emitter terminal of the first low-side transistor 440, and as such, the first low-side transistor 440 is turned off, and electrical current may not flow between its collector and emitter terminals. Consequently, the voltage at the base terminal of the second low-side transistor 442 may be infinite, due to the open circuit resulting from the first low-side transistor 440 being turned off. As a result, the second low-side transistor 442 may also be turned off, and electrical current may not flow between its collector and emitter terminals.

Still referring to FIG. 3, according to various embodiments, the interface circuit 100 may further include a diode device 402 between the switching circuit 130 and the first connection circuit 110. The diode device 402 may be connected between the switching circuit 130 and the wetting current resistor 304. The diode device 402 may also be connected between the switching circuit 130 and the jumper cable 302. The diode device 402 may restrict electrical current to flow unidirectionally from the high-side switch 132 to the first connection circuit 110. The diode device 402 may restrict electrical current to flow unidirectionally from the first connection circuit 110 to the low-side switch 134. The diode device 402 may include, for example, at least one diode. The diode device 402 may be connected to the respective collector terminals of the second high-side transistor 432 and the second low-side transistor 442.

Still referring to FIG. 3, according to various embodiments, the surge protection sub-circuit 112 may include a capacitor 410 and a diode device 412 connected in parallel. The diode device 412 may be a back-to-back transient-protection diode. The diode device 412 may be configured to protect the interface circuit 100 from being damaged when there is a transient surge in the input voltage provided to the first connection circuit 112.

Still referring to FIG. 3, according to various embodiments, the diagnostic sub-circuit 124 may include a first resistor 422 and a second resistor 424. The diagnostic sub-circuit 124 may be configured to detect an open circuit, for example, when the interface circuit 100 is disconnected from the load device or sensor device. The diagnostic sub-circuit 124 may include a voltage divider. The diagnostic sub-circuit 124 may include a first resistor 422 and a second resistor 424, arranged to form the voltage-divider, referenced to V_{cc} 426. The first resistor 422 may be connected between V_{cc} 426 and the first connection circuit 110. The second resistor 424 may be connected between the first connection circuit 110 and electrical ground. The resistance value of resistor 424 may be selected such that it is much higher that the load or sensor's direct current resistance, to have a minimal loading effect on the output or the sensor resistance. If load device or sensor device is disconnected from the interface circuit 100, in other words, no device is connected to the interface circuit 100, the input signal 102 may be a stepped-down level of V_{cc} 426 resulting from the voltage-divider. The diagnostic sub-circuit 124 may further include a diode device 420 connected to the first resistor 422. The diode device 420 may be connected to both V_{cc} 426 and to an electrical ground. The diode device 420 may restrict electrical current to flow unidirectionally from V_{cc} 426 to the first resistor 422. The diode device 420 may restrict electrical current to flow unidirectionally from V_{cc} 426 to the first resistor 422. The diode device 420 may also restrict electrical current to flow unidirectionally from the first resistor 422 to the electrical ground.

Still referring to FIG. 3, according to various embodiments, the level-shifter sub-circuit 122 may include a third resistor 450, a fourth resistor 452 and a capacitor 454. The fourth resistor 452 and the capacitor 454 may be connected in parallel. The third resistor 450 may be connected in series, to each of the fourth resistor 452 and the capacitor 454.

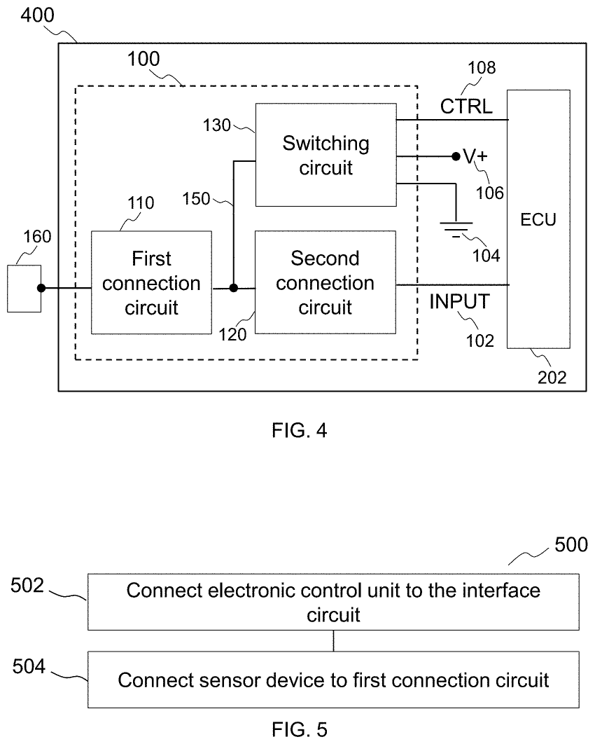

FIG. 4 shows an ECU system 400 according to various embodiments. The ECU system 400 may include the interface circuit 100 as described in any of the above embodiments. The ECU system 400 may further include an ECU 202 connected to the interface circuit 100. The ECU system 400 may be connected to an external device 160, through the first connection circuit 110 of the interface circuit 100.

FIG. 5 shows a flow diagram of a method 500 of operating a sensor device using an ECU, according to various embodiments. The method 500 may include connecting the ECU 202 to the interface circuit 100 as described in any of the above embodiments, in 502. The method 500 may include connecting the sensor device to the first connection circuit 110 of the interface circuit 100, in 504. The first connection circuit 110 may be connected to the switching circuit 130 via the wetting current resistor 304.

According to an embodiment which may be combined with any above-described embodiment or with any below described further embodiment, the method 500 may further include receiving a sensor output signal through the first connection circuit 110, and providing the input signal 102 to the ECU based on the received sensor output signal, by the second connection circuit 120. The input signal 102 may be indicative of the sensor output signal.

According to an embodiment which may be combined with any above-described embodiment or with any below described further embodiment, the method 500 may further include connecting the sensor device to a supply voltage external to the interface circuit 100, and setting the control signal 108 to logic LOW.

According to an embodiment which may be combined with any above-described embodiment or with any below described further embodiment, the method 500 may further include connecting the sensor device to an electrical ground external to the interface circuit 100, and setting the control signal 108 to logic HIGH.

Various aspects of the method 500 described may also apply to the use of any of the above-described interface circuits 100 for operating a sensor device using an ECU.

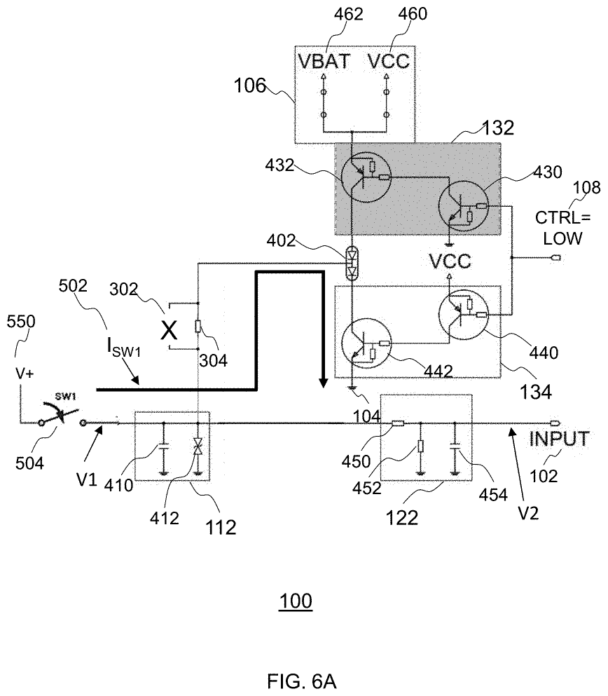

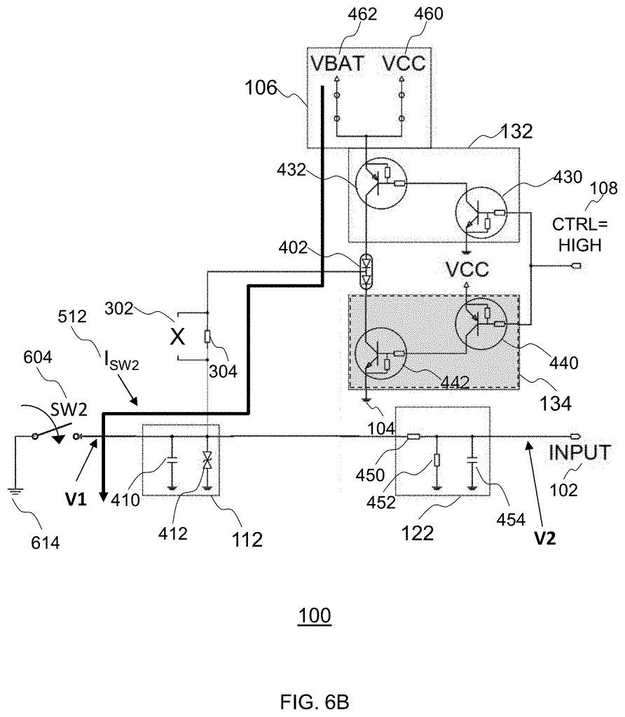

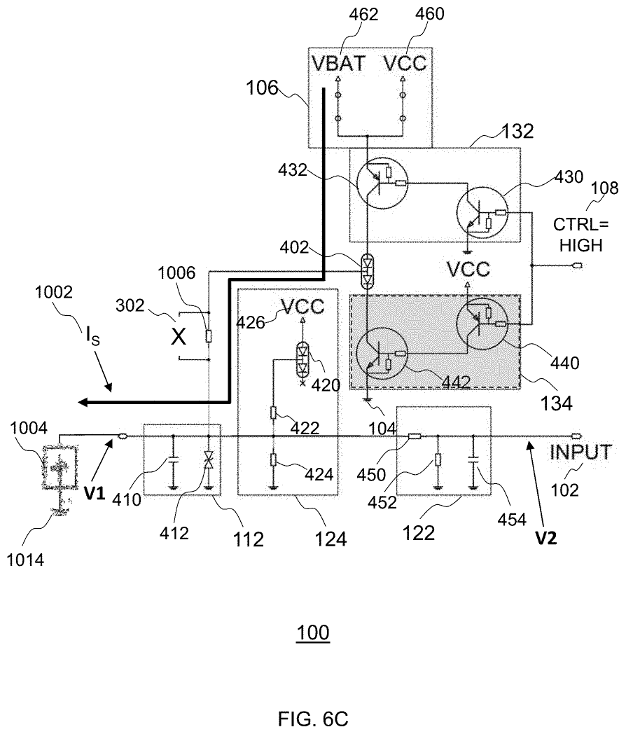

FIG. 6A shows an annotated circuit diagram of the interface circuit 100, when the interface circuit 100 is in use to carry out the method 500, according to various embodiments. In the example shown, the interface circuit 100 may be connected to an active-high sensor device 504, represented by the switch “SW1”. The active-high sensor device 504 may be connected to a supply voltage 550. The active-high sensor device 504, when in use, may transmit a high voltage sensor signal (denoted as V1) to the interface circuit 100. The interface circuit 100 may be configurable to sense readings from an active-high sensor device 504, by using the ECU 202 to set the control signal 108 as LOW. When the control signal 108 is LOW, the high-side switch 132 may be turned off (shown in FIG. 6A as being grayed out), while the low-side switch 134 may be turned on. In other words, the first connection circuit 110 may be connected to the first voltage 104 while being disconnected from the second voltage 106. As a result, an electrical current (denoted as I_{sw1} 502) may flow from the active-high sensor device 504 to the first voltage 104. I_{sw1} 502 may flow from the active-high sensor device 504 to the first connection circuit 110, and from the first connection circuit 110 to the low-side switch 134 of the switching circuit 130. The jumper cable 302 may be disconnected so that I_{sw1} 502 flows from the first connection circuit 110 to the switching circuit 130 via the wetting current resistor 304. The electrical current I_{sw1} 502 may be expressed as:

I_{SW1}=V_{IN}−V_{F}_{_{D1}}−V_{CE_T2_npn}/R1,

where R1 denotes the wetting current resistor 304, V_{IN} denotes V1, V_{FD1} denotes voltage across the diode device 402, and V_{CE_T2_npn} denotes the collector-emitter voltage of the second low-side transistor 442.

The interface circuit 100 need not include the diagnostic sub-circuit 124 for performing the method 500. The first connection circuit 110 may receive the sensor signal V1 from the active-high sensor device 504. The second connection circuit 110 may receive the same sensor signal V1 either directly from the active-low sensor device 604 or through the first connection circuit 110, and may transmit a translated sensor signal V2 to the ECU 202 based on the sensor signal V1. In other words, the input signal 102 may be V2.

V2 may be expressed as:

$$V 2 = {V}_{IN} \cdot \frac{{R}_{4}}{{R}_{4} + {R}_{3}} and \\ {V}_{IH \_ low} \geq V 2 \geq {V}_{IH \_ high} ,$$

wherein R₃ denotes the third resistor 450 and R₄ denotes the fourth resistor 452, while V_{1H_high} denotes the maximum voltage receivable by the ECU 202 and V_{1H_low} denotes the minimum voltage receivable by the ECU 202.

FIG. 6B shows an annotated circuit diagram of the interface circuit 100, when the interface circuit 100 is in use to carry out the method 500, according to various embodiments. In the example shown, the interface circuit 100 may be connected to an active-low sensor device 604, represented by the switch “SW2”. The active-low sensor device 604 may be connected to electrical ground 614. The active-low sensor device 604, when in use, may transmit a low voltage sensor signal (denoted as V1) to the interface circuit 100. The interface circuit 100 may be configurable to sense readings from an active-low sensor device 604, by using the ECU 202 to set the control signal 108 as HIGH. When the control signal 108 is HIGH, the high-side switch 132 may be turned on, while the low-side switch 134 may be turned off (shown in FIG. 6B as being grayed out). In other words, the first connection circuit 110 may be connected to the second voltage 106 while being disconnected from the first voltage 104. In the circuit providing the second voltage 106, V_{cc} 460 may be disconnected such that only V_{BAT} 462 remains connected to the high-side switch 132. Disconnecting V_{cc} 460 may prevent electrical current from V_{BAT} 462 from flowing into V_{cc} 460 and causing damage to the V_{cc} 460 supply circuit. As a result of connecting the first connection circuit 110 to the second voltage 106, an electrical current (denoted as I_{sw2} 512) may flow from the second voltage 106 to the active-low sensor device 512. I_{sw2} 512 may flow from the second voltage 106 to the high-side switch 132 of the switching circuit 130, then from the high-side switch 132 to the first connection circuit 110, and then from the first connection circuit 110 to the electrical ground 614. The jumper cable 302 may be disconnected so that I_{sw2} 512 flows from the switching circuit 130 to the first connection circuit 110 via the wetting current resistor 304. The electrical current I_{SW2} 512 may be expressed as:

$${I}_{S W 2} = \frac{{V}_{B A T} - {V}_{EC \_ T 1 \_ pnp} - {V}_{F \_ D 1}}{R 1} ,$$

where R1 denotes the wetting current resistor 304, V_{BAT} denotes the voltage provided by V_{BAT} 462, V_{EC_T1_pnp} denotes emitter-collector voltage of the second high-side transistor 432, and V_{F_D1} denotes the voltage across the diode device 402.

The interface circuit 100 need not include the diagnostic sub-circuit 124 for performing the method 500. The first connection circuit 110 may receive the sensor signal V1 from the active-low sensor device 604. The second connection circuit 110 may receive the same sensor signal V1, either directly from the active-low sensor device 604 or through the first connection circuit 110, and may transmit a translated sensor signal V2 to the ECU 202 based on the sensor signal V1. In other words, the input signal 102 may be V2.

V2 may be expressed as:

$$V 2 = {V}_{IN} \cdot \frac{{R}_{4}}{{R}_{4} + {R}_{3}} and \\ {V}_{IH \_ low} \geq V 2 \geq {V}_{IH \_ high} ,$$

wherein R₃ denotes the third resistor 450 and R4 denotes the fourth resistor 452, while V_{1H_high} denotes the maximum voltage receivable by the ECU 202 and V_{1H_low} denotes the minimum voltage receivable by the ECU 202.

FIG. 6C shows an annotated circuit diagram of the interface circuit 100, when the interface circuit 100 is in use to carry out the method 500, according to various embodiments. In the example shown, the interface circuit 100 may be connected to a ratiometric sensor device 1004. A ratiometric sensor device 1004 may output a sensor voltage that depends on the varying resistance of the ratiometric sensor device 1004. The resistance of the ratiometric sensor device 1004 may vary according to a parameter that the ratiometric sensor device 1004 is measuring. In other words, the voltage level of the sensor voltage may indicate a measurement made by the ratiometric sensor device 1004. The interface circuit 100 may be used to perform sensor voltage sensing, in other words, to determine an output voltage of the ratiometric sensor device 1004. A well-regulated, precision voltage source may be connected to the second voltage 106, to serve as the sensor supply voltage. The ratiometric sensor device 1004 may be connected to electrical ground 1014. A reference resistor 1006 may be connected between the switching circuit 130 and the first connection circuit 110, in place of the wetting current resistor 304. The jumper cable 302 may be disconnected so that Is 1002 flows from the switching circuit 130 to the first connection circuit 110 via the reference resistor 1006. The reference resistor 1006 may differ from the wetting current resistor 304 in its resistance value. The resistance value of the reference resistor 1006 may be selected in view of the resistance value of the ratiometric sensor device 1004.

The interface circuit 100 may be configurable to sense readings from the ratiometric sensor device 1004, by setting the control signal 108 as HIGH. When the control signal 108 is HIGH, the high-side switch 132 may be turned on, while the low-side switch 134 may be turned off (shown in FIG. 6C as grayed out). In other words, the first connection circuit 110 may be connected to the second voltage 106 while being disconnected from the first voltage 104. As a result, an electrical current (denoted as Is 1002) may flow from the second voltage 106 to the ratiometric sensor device 1004. Is 1002 may flow from the second voltage 106 to the high-side switch 132 of the switching circuit 130, then from the high-side switch 132 to the first connection circuit 110, and then from the first connection circuit 110 to the ratiometric sensor device 1004. The electrical current Is 1002 may be expressed as:

$${I}_{S} = \frac{{V}_{S S} - {V}_{EC \_ T 1 \_ pnp} - {V}_{F \_ D 1}}{Rref} ,$$

where Rref denotes the reference resistor 1006, Vₛₛ denotes the sensor supply voltage provided by the second voltage 106, V_{Ec_T1_pnp} denotes emitter-collector voltage of the second high-side transistor 432, and V_{F_D1} denotes the voltage across the diode device 402.

The first connection circuit 110 may receive the sensor signal V1 from the ratiometric sensor device 1004. The second connection circuit 110 may receive the same sensor signal V1, either directly from the active-low sensor device 604 or through the first connection circuit 110, and may transmit a translated sensor signal V2 as the input signal 102, to the ECU 202 based on the sensor signal V1.

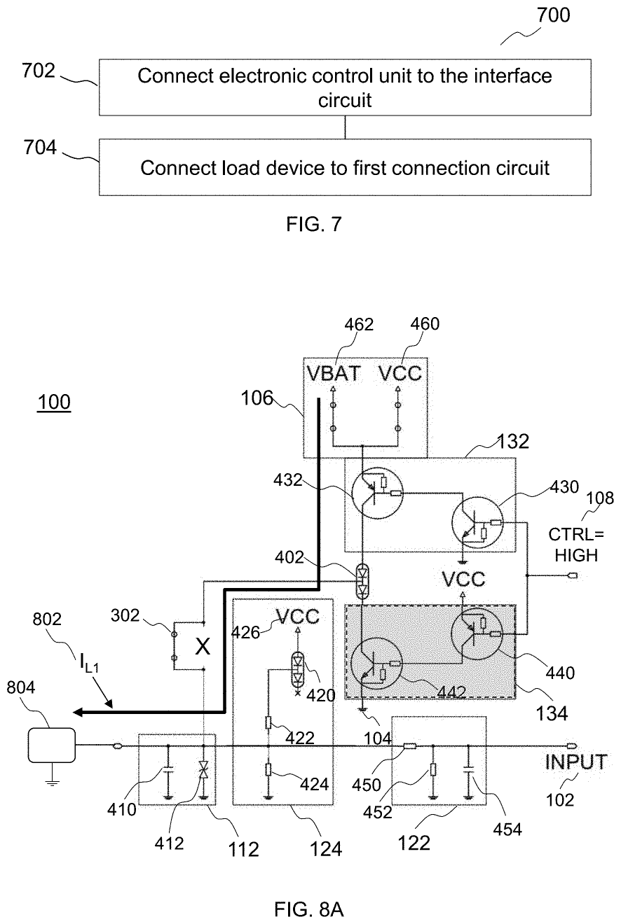

FIG. 7 shows a flow diagram of a method 700 of operating a load device using an ECU, according to various embodiments. The method 700 may include connecting the ECU 202 to the interface circuit 100 as described in any of the above embodiments, in 702. The method 700 may include connecting the load device to the first connection circuit 110 of the interface circuit 100, in 704. The first connection circuit 110 may be connected to the switching circuit 130 via the jumper cable 302.

According to an embodiment which may be combined with any above-described embodiment or with any below described further embodiment, the method 700 may further include connecting the load device to an electrical ground external to the interface circuit 100, and setting connecting the switching circuit 130 to the second voltage 106.

According to an embodiment which may be combined with any above-described embodiment or with any below described further embodiment, the method 700 may further include setting the control signal 108 to logic HIGH to turn on the load device, and setting the control signal to logic LOW to turn off the load device.

According to an embodiment which may be combined with any above-described embodiment or with any below described further embodiment, the method 700 may further include connecting the load device to a supply voltage external to the interface circuit 100, and setting the control signal 108 to logic LOW to turn on the load device.

The above-described aspects of the method 700 may also apply to the use of any of the above-described interface circuits 100 for operating a load device using an ECU.

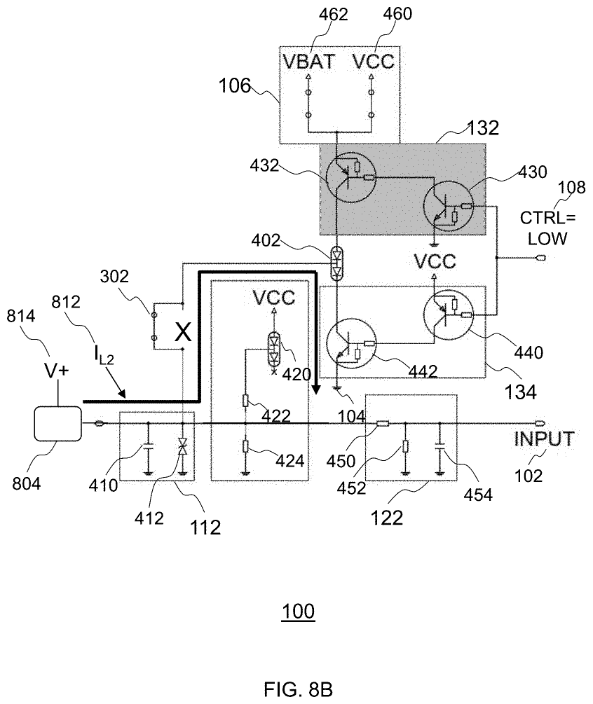

FIG. 8A shows an annotated circuit diagram of the interface circuit 100, when the interface circuit 100 is in use to carry out the method 700, according to various embodiments. In the example shown, the interface circuit 100 may be used as a high-side output driver to drive a load device 804. The load device 804 may be an automotive load apparatus, for example, an automotive relay, an automotive solenoid, or a lamp. When the interface circuit 100 is used as a high-side output driver, the interface circuit 100 may connect to the second voltage 106, and may connect the load device 804 to the second voltage 106 via the interface circuit 100. The load device 804 may be connected to electrical ground.

The interface circuit 100 may be configurable to function as a high-side output driver, by using the ECU 202 to set the control signal 108 as HIGH. When the control signal 108 is HIGH, the high-side switch 132 may be turned on, while the low-side switch 134 may be turned off (shown in FIG. 8A as being grayed out).

In other words, the first connection circuit 110 may be connected to the second voltage 106 while being disconnected from the first voltage 104. As a result, an electrical current (denoted as I_{L1} 802) may flow from the second voltage 106 to the load device 804. I_{L1} 802 may flow from the second voltage 106 to the high-side switch 132 of the switching circuit 130, then from the high-side switch 132 to the first connection circuit 110, and then from the first connection circuit 110 to the load device 804. As a result, the load device 804 may be powered on.

The wetting current resistor 304 may be disconnected so that I_{L1} 802 flows from the switching circuit 130 to the first connection circuit 110 via the jumper cable 302. The electrical current I_{L1} 802 may be expressed as:

$${I}_{L 1} = \frac{{V}_{S} - {V}_{EC \_ T 1 \_ pnp} - {V}_{F \_ D 1}}{{R}_{L}} ,$$

where R_{L} denotes the resistance of the load device 804, Vs denotes the voltage provided by the power supply 106, V_{Ec_T1_pnp} denotes emitter-collector voltage of the second high-side transistor 432, and V_{F_D1} denotes the voltage across the diode device 402.

To turn off the load device 804, the control signal 108 may be set to LOW, so that the high-side switch 132 is turned off and the load device 804 is thereby disconnected from the power supply 106.

In an embodiment, the low-side switch 134 may be removed from the switching circuit 130, for high-side output driving operations, to avoid the low-side switch 134 from affecting the high-side output driving operations, and to reduce the material cost of the interface circuit 100.

FIG. 8B shows an annotated circuit diagram of the interface circuit 100, when the interface circuit 100 is in use to carry out the method 700, according to various embodiments. In the example shown, the interface circuit 100 may be used as a low-side output driver to drive the load device 804. When the interface circuit 100 is used as a low-side output driver, the interface circuit 100 may connect the load device 804 to the first voltage 104. The load device 804 may be connected to an external supply voltage 814. The interface circuit 100 may be configurable to function as a low-side output driver, by using the ECU 202 to set the control signal 108 as LOW. When the control signal 108 is LOW, the low-side switch 134 may be turned on, while the high-side switch 132 may be turned off (shown in FIG. 8B as being grayed out). In other words, the first connection circuit 110 may be connected to the first voltage 104 while being disconnected from the second voltage 106. As a result, an electrical current (denoted as I_{L2} 812) may flow from the load device 804 to the first voltage 104. I_{L2} 802 may flow from the external supply voltage 814 to the load device 804, and from the load device 804 to the low-side switch 134 of the switching circuit 130. As a result, the load device 804 may be powered on.

The wetting current resistor 304 may be disconnected so that I_{L2} 812 flows from the first connection circuit 110 to the switching circuit 130 via the jumper cable 302. The electrical current I_{L2} 812 may be expressed as:

$${I}_{L 2} = \frac{{V}_{IN} - {V}_{{F}_{D 1}} - {V}_{CE \_ T 2 \_ npn}}{{R}_{L}} ,$$

where R_{L} denotes the resistance of the load device 804, V_{IN} denotes the voltage provided by the external supply voltage 814, V_{FD1} denotes voltage across the diode device 402, and V_{CE_T2_npn} denotes the collector-emitter voltage of the second low-side transistor 442.

To turn off the load device 804, the control signal 108 may be set to HIGH, so that the low-side switch 134 is turned off and electrical current does not flow due to the resulting open circuit.

In an embodiment, the high-side switch 132 may be removed from the switching circuit 130, for low-side output driving operations, to avoid the high-side switch 132 from affecting the low-side output driving operations, and to reduce the material cost of the interface circuit 100.

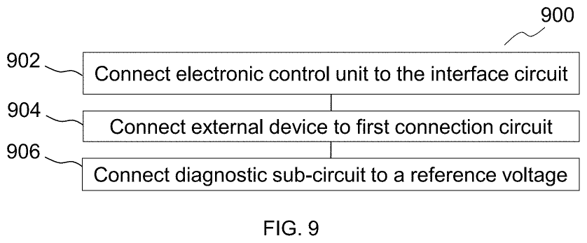

FIG. 9 shows a flow diagram of a method 900 of diagnosing for fault conditions in an external device using an ECU, according to various embodiments. The external device may be a sensor device, or may also be a load device. The method 900 may include connecting the ECU 202 to the interface circuit 100 as described in any of the above embodiments, in 902. The method 900 may include connecting the external device to the first connection circuit 110 of the interface circuit 100, in 904. The method 900 may include connecting a diagnostic sub-circuit 124 of the interface circuit 100 to a reference voltage, in 906. The method 900 will be described further with respect to FIGS. 6C, 8A and 8B, in the following paragraphs.

According to various embodiments, when the interface circuit 100 is used to perform the methods 500 or 700, the second connection circuit 120 may optionally further include the diagnostic sub-circuit 124, so that the interface circuit 100 may also carry out the method 900, to diagnose fault condition in an external device. The ECU may provide a reference voltage, VREF_DIAG to the diagnostic sub-circuit 124 at the V_{cc} 426. The diagnostic sub-circuit 124 may receive a first signal from the first connection circuit 110. The diagnostic sub-circuit 124 may transmit a second signal to the level-shifter sub-circuit 122 based on the first signal. The voltage level of the second signal may differ based on the fault condition of the external device. The level-shifter sub-circuit 122 may transmit the input signal 102 to the ECU, based on the second signal. The input signal 102 may thus be indicative of a fault condition at the external device.

Referring to FIG. 6C, the interface circuit 100 may be configured to detect fault conditions when the interface circuit 100 is connected to a ratiometric sensor device 1004. The diagnostic sub-circuit 124 may be configured to detect a fault at the ratiometric sensor device 1004 or the connection between the ratiometric sensor device 1004 and the interface circuit 100. To carry out the method 900 for the ratiometric sensor device 1004, the control signal 108 may be set to LOW (not shown in FIG. 6C), so that the ratiometric sensor device 1004 is disconnected from the second voltage 106. A reference voltage VREF_DIAG may also be supplied to the diagnostic sub-circuit 124 at the V_{cc} 426.

If the ratiometric sensor device 1004 or the connection between the first connection circuit and the ratiometric sensor device 1004 is shorted to ground, the diagnostic sub-circuit 124 may receive a 0V signal from the first connection circuit 110, and consequently, the input signal 102 may be 0V.

If the ratiometric sensor device 1004 or the connection between the first connection circuit and the ratiometric sensor device 1004 is shorted to battery, an electrical current may flow from the battery to the electrical ground in the diagnostic sub-circuit 124. The diagnostic sub-circuit 124 may output a large voltage signal. The level-shifter sub-circuit 122 may translate the large voltage signal to the maximum safe voltage for the ECU port, as the input signal 102.

If the ratiometric sensor device 1004 is disconnected from the first connection circuit 110, i.e., there is an open circuit at the interface circuit 100, the diagnostic sub-circuit 124 may output the second signal based on a division of the VREF_DIAG based on its first resistor 422 and second resistor 424. The input signal 102 may thus be higher than the load voltage level at the maximum load direct-current resistance value. The input signal 102 may have different voltage levels under different fault conditions, and thus provide an indication as to the status of the connection to the ratiometric sensor device 1004. The ECU 202 may diagnose the condition of the ratiometric sensor device 1004 connected to the interface circuit 100 based on the input signal 102.

Referring to FIG. 8A, when the interface circuit 100 is used to run high-side output drive operations, the diagnostic sub-circuit 124 may be used to perform high-side output diagnostics before the load device 804 is energized, i.e., when the control signal 108 is LOW (not shown in FIG. 8A).

If the load device 804 or the connection between the first connection circuit and the load device 804 is shorted to ground, the diagnostic sub-circuit 124 may receive a 0V signal from the first connection circuit 110, and consequently, the input signal 102 may be 0V.

If the load device 804 or the connection between the first connection circuit and the load device 804 is shorted to battery, an electrical current may flow from the battery to the electrical ground in the diagnostic sub-circuit 124. The diagnostic sub-circuit 124 may output a large voltage signal. The level-shifter sub-circuit 122 may translate the large voltage signal to the maximum safe voltage for the ECU port, as the input signal 102.

If the load device 804 is disconnected from the first connection circuit 110, i.e., there is an open circuit at the interface circuit 100, the diagnostic sub-circuit 124 may output the second signal based on a division of the VREF_DIAG based on its first resistor 422 and second resistor 424. The input signal 102 may thus be higher than the load voltage level at the maximum load direct-current resistance value. The input signal 102 may have different voltage levels under different fault conditions, and thus provide an indication as to the status of the connection to the load device 804. The ECU 202 may diagnose the condition of the load device 804 connected to the interface circuit 100 based on the input signal 102.

Referring to FIG. 8B, when the interface circuit 100 is used to run low-side output drive operations, the diagnostic sub-circuit 124 may be used to perform low-side output diagnostics before the load device 804 is energized, i.e., when the control signal 108 is HIGH (not shown in FIG. 8B).

If the load device 804 or the connection between the first connection circuit and the load device 804 is shorted to ground, the diagnostic sub-circuit 124 may receive a 0V signal from the first connection circuit 110, and consequently, the input signal 102 may be 0V.

If the load device 804 or the connection between the first connection circuit and the load device 804 is shorted to battery, the diagnostic sub-circuit 124 may receive a voltage signal that is higher as compared to the voltage level if the load device 804 is not shorted, due to the direct current resistance of the load device 804. The diagnostic sub-circuit 124 may output the second signal based on the received higher voltage signal.

If the load device 804 is disconnected from the first connection circuit 110, i.e., there is an open circuit at the interface circuit 100, the diagnostic sub-circuit 124 may output the second signal based on a division of the VREF_DIAG based on its first resistor 422 and second resistor 424. The input signal 102 may thus be higher than the load voltage level at the maximum load direct-current resistance value. The input signal 102 may have different voltage levels under different fault conditions, and thus provide an indication as to the status of the connection to the load device 804. The ECU 202 may diagnose the condition of the load device 804 connected to the interface circuit 100 based on the input signal 102.

The following examples described further technical aspects of the devices, systems and methods described above and shall not be interpreted as claims.

The following examples can additionally be combined with any of the devices, systems and methods as described above, any of the claims as originally filed.

Example 1 is an interface circuit for connecting to an electronic control unit, the interface circuit including: a first connection circuit configured to connect to an external device; a second connection circuit configured to provide an input signal to an electronic control unit, the input signal indicative of a voltage level at the first connection circuit; and a switching circuit connectable to a first voltage and a second voltage, wherein the switching circuit is configured to receive a control signal from the electronic control unit, and further configured to selectively connect the first connection circuit to one of the second voltage and the first voltage, based on the received control signal.

In example 2, the subject-matter of example 1 can optionally include that the switching circuit includes a high-side switch connectable to the second voltage and a low-side switch connectable to the first voltage, wherein the switching circuit is configured to selectively switch on only one of the high-side switch and the low-side switch, based on the received control signal.

In example 3, the subject-matter of example 2 can optionally include that the high-side switch includes a first high-side transistor configured to receive the control signal and further includes a second high-side transistor connectable to the second voltage, wherein the first high-side transistor is configured to switch on the second high-side transistor based on the received control signal.

In example 4, the subject-matter of example 3 can optionally include that each of the first high-side transistor and the second high-side transistor is a bipolar junction transistor, wherein a base terminal of the first high-side transistor is configured to receive the control signal, wherein a collector terminal of the first high-side transistor is connected to a base terminal of the second high-side transistor, and wherein an emitter terminal of the second high-side transistor is connectable to the second voltage.

In example 5, the subject-matter of any one of examples 2 to 4 can optionally include that the low-side switch includes a first low-side transistor configured to receive the control signal and further includes a second low-side transistor connectable to the first voltage, wherein the first low-side transistor is configured to switch on the second low-side transistor based on the received control signal.

In example 6, the subject-matter of example 5 can optionally include that each of the first low-side transistor and the second low-side transistor is a bipolar junction transistor, wherein a base terminal of the first low-side transistor is configured to receive the control signal, wherein a collector terminal of the first low-side transistor is connected to a base terminal of the second low-side transistor, and wherein an emitter terminal of the second low-side transistor is connectable to the first voltage.

In example 7, the subject-matter of example of any one of examples 1 to 6 can optionally include that the first connection circuit is connected to the switching circuit via one of a wetting current resistor and a jumper cable.

In example 8, the subject-matter of example of any one of examples 1 to 7 can optionally include that the first connection circuit is configured to at least partially absorb voltage surges.

In example 9, the subject-matter of example of any one of examples 1 to 8 can optionally include that the second connection circuit includes a level-shifter sub-circuit configured to translate the voltage level at the first connection circuit to a safe voltage level for the electronic control unit, as the input signal.

In example 10, the subject-matter of example of any one of examples 1 to 9 can optionally include that the second connection circuit includes a diagnostic sub-circuit configured to detect a fault at the external device, and further configured to provide an error signal as the input signal based on detection of the fault.

Example 11 is an electronic control unit system including: the interface circuit of any one of examples 1 to 10; and an electronic control unit connected to the interface circuit.

Example 12 is a method of operating a sensor device using an electronic control unit, the method including: connecting the electronic control unit to the interface circuit of any one of examples 1 to 10; and connecting the sensor device to the first connection circuit, wherein the first connection circuit is connected to the switching circuit via a wetting current resistor.

In example 13, the subject-matter of example 12 can optionally include: receiving a sensor output signal through the first connection circuit; and providing the input signal to the electronic control unit based on the received sensor output signal, by the second connection circuit, wherein the input signal is indicative of the sensor output signal.

Example 14 is a method of operating a load device using an electronic control unit, the method including: connecting the electronic control unit to the interface circuit of any one of examples 1 to 10; and connecting the load device to the first connection circuit, wherein the first connection circuit is connected to the switching circuit via a jumper cable.

Example 15 is a method of diagnosing for fault conditions in an external device using an electronic control unit, the method including: connecting the electronic control unit to the interface circuit of any one of examples 1 to 10; connecting the external device to the first connection circuit; and connecting a diagnostic sub-circuit of the interface circuit to a reference voltage.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced. It will be appreciated that common numerals, used in the relevant drawings, refer to components that serve a similar or the same purpose.

It will be appreciated to a person skilled in the art that the terminology used herein is for the purpose of describing various embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims.

1. An interface circuit for connecting to an electronic control unit, the interface circuit comprising:
a first connection circuit configured to connect to an external device;
a second connection circuit configured to provide an input signal to the electronic control unit, the input signal indicative of a voltage level at the first connection circuit; and
a switching circuit connectable to a first voltage and a second voltage,
wherein the switching circuit is configured to receive a control signal from the electronic control unit, and further configured to selectively connect the first connection circuit to one of the second voltage and the first voltage, based on the received control signal.

2. The interface circuit of claim 1, wherein the switching circuit comprises a high-side switch connectable to the second voltage and a low-side switch connectable to the first voltage, wherein the switching circuit is configured to selectively switch on only one of the high-side switch and the low-side switch, based on the received control signal.

3. The interface circuit of claim 2, wherein the high-side switch comprises a first high-side transistor configured to receive the control signal and further comprises a second high-side transistor connectable to the second voltage, wherein the first high-side transistor is configured to switch on the second high-side transistor based on the received control signal.

4. The interface circuit of claim 3, wherein the low-side switch comprises a first low-side transistor configured to receive the control signal and further comprises a second low-side transistor connectable to the first voltage, wherein the first low-side transistor is configured to switch on the second low-side transistor based on the received control signal.

5. The interface circuit of claim 3, wherein the first connection circuit is connected to the switching circuit via one of a wetting current resistor and a jumper cable.

6. The interface circuit of claim 3, wherein each of the first high-side transistor and the second high-side transistor is a bipolar junction transistor, wherein a base terminal of the first high-side transistor is configured to receive the control signal, wherein a collector terminal of the first high-side transistor is connected to a base terminal of the second high-side transistor, and wherein an emitter terminal of the second high-side transistor is connectable to the second voltage.

7. The interface circuit of claim 6, wherein the low-side switch comprises a first low-side transistor configured to receive the control signal and further comprises a second low-side transistor connectable to the first voltage, wherein the first low-side transistor is configured to switch on the second low-side transistor based on the received control signal.

8. The interface circuit of claim 6, wherein the first connection circuit is connected to the switching circuit via one of a wetting current resistor and a jumper cable.

9. The interface circuit of claim 2, wherein the low-side switch comprises a first low-side transistor configured to receive the control signal and further comprises a second low-side transistor connectable to the first voltage, wherein the first low-side transistor is configured to switch on the second low-side transistor based on the received control signal.

10. The interface circuit of claim 9, wherein each of the first low-side transistor and the second low-side transistor is a bipolar junction transistor, wherein a base terminal of the first low-side transistor is configured to receive the control signal, wherein a collector terminal of the first low-side transistor is connected to a base terminal of the second low-side transistor, and wherein an emitter terminal of the second low-side transistor is connectable to the first voltage.

11. The interface circuit of claim 2, wherein the first connection circuit is connected to the switching circuit via one of a wetting current resistor and a jumper cable.

12. The interface circuit of claim 1, wherein the first connection circuit is connected to the switching circuit via one of a wetting current resistor and a jumper cable.

13. The interface circuit of claim 1, wherein the first connection circuit is configured to at least partially absorb voltage surges.

14. The interface circuit of claim 1, wherein the second connection circuit comprises a level-shifter sub-circuit configured to translate the voltage level at the first connection circuit to a safe voltage level for the electronic control unit, as the input signal.

15. The interface circuit of claim 1, wherein the second connection circuit comprises a diagnostic sub-circuit configured to detect a fault at the external device, and further configured to provide an error signal as the input signal based on detection of the fault.

16. An electronic control unit system comprising:
the interface circuit of claim 1; and
the electronic control unit connected to the interface circuit.

17. A method of operating a sensor device using a electronic control unit, the method comprising:
connecting the electronic control unit to the interface circuit of claim 1; and
connecting the sensor device to the first connection circuit, wherein the first connection circuit is connected to the switching circuit via a wetting current resistor.

18. The method of claim 17, further comprising:
receiving a sensor output signal through the first connection circuit; and
providing the input signal to the electronic control unit based on the received sensor output signal, by the second connection circuit, wherein the input signal is indicative of the sensor output signal.

19. A method of operating a load device using an electronic control unit, the method comprising:
connecting the electronic control unit to the interface circuit of claim 1; and
connecting the load device to the first connection circuit, wherein the first connection circuit is connected to the switching circuit via a jumper cable.

20. A method of diagnosing for fault conditions in an external device using an electronic control unit, the method comprising:
connecting the electronic control unit to the interface circuit of claim 1;
connecting the external device to the first connection circuit; and
connecting a diagnostic sub-circuit of the interface circuit to a reference voltage.
